(19) United States
(12) Patent Application Publication
(10) Pub. No.: US 2009/0146281 A1
(43) Pub. Date: Jun. 11, 2009

(54) SYSTEM IN PACKAGE AND FABRICATION METHOD THEREOF

(75) Inventor: Gi Jo JUNG, Incheon-si (KR)

Correspondence Address: HOSOON LEE, 9600 SW OAK ST. SUITE 525, TIGARD, OR, 97223, US

(73) Assignee: NEPES CORPORATION, Chungbuk (KR)

(21) Appl. No.: 12/111,892

(22) Filed: Apr. 29, 2008

(30) Foreign Application Priority Data
Dec. 10, 2007 (KR) 2007-127710

(51) Int. Cl. H01L 23/00; H01L 21/50

(52) U.S. Cl. 257/678; 438/121; 257/E23.001; 257/E21.499

(57) ABSTRACT

There is provided a system-in-package including: a substrate of a sawed base wafer on which a semiconductor circuit is formed; a conductive post formed on a top surface of the substrate; at least one semiconductor chip stacked on the top surface of the substrate; a buried layer formed on the top surface of the substrate so as to cover at least partially the conductive post and the semiconductor chip; and an external connection bump electrically connected to the conductive post. The system-in-package is fabricated by stacking a plurality of semiconductor chips on a top surface of a base wafer, forming a buried layer, realizing an electrical path by a conductive post, and polishing top and bottom surfaces of the package, thereby thinning the thickness of the package. Further, the system-in-package greatly improves electrical operation characteristics and increases productivity.

### CROSS-REFERENCE TO RELATED APPLICATION

This application claims the benefit of Korean Patent Application No. 2007-127710, filed Dec. 10, 2007, the disclosure of which is hereby incorporated herein by reference in its entirety.

### BACKGROUND OF THE INVENTION

The present invention relates to a system-in-package (SIP) and a fabrication method thereof, wherein a base substrate and a semiconductor chip are stacked and a buried layer is formed at a wafer level, thereby proposing a new integrated package thinned in thickness.

The technology has been continuously developed to reduce the size of a system by integrating semiconductor components within a substrate and to improve the integration density. Further, a system-on-chip has been proposed to integrate many circuit components into a single chip. However, the effort of realizing circuit integration only through the system-on-chip of stacking various circuits on the single chip has technical limitations. Therefore, many stacking technologies, such as system-in-package (SiP), system-on-package (SoP), package-on-package (PoP), multi-chip package (MCP) and the like, have been proposed to overcome the limitations of the circuit integration.

In the MCP technology of integrating a number of memory chips, a high capacity package has been realized by stacking memories up to sixteen (16) layers. While the MCP technology stacks only memories, the technologies of SiP, SoP, PoP and the like integrate memories with non-memories of a system semiconductor and the like or integrate a system semiconductor with a system semiconductor as one. The SiP, SoP, PoP and the like stack each of the layers having diverse functions or connect the layers side by side. In the SiP, a plurality of circuits each comprising a separate chip is connected side by side to be mounted as a single package.

Research has been speedily directed towards the integrated package, such as the MCP, SiP and the like, at home and abroad. Furthermore, demands for the high-tech integrated package market have increased as mobile communication machinery and tools and the like need to have high-performance and to be thinner. Specifically, as application products, such as mobile phones, PDA, DSC and the like, are manufactured so as to be small, highly functionalized and slim, attempts to bury passive and active devices within a package substrate and a main board are actively conducted.

In a conventional integrated package, a buried lamination structure is completed by a sequential build-up method of laminating an insulating material, such as resin, onto a substrate, such as a package substrate, a main board or the like; forming a hole to bury a device; burying a passive or active device into the hole; and forming an inter-insulating layer above the hole.

However, in the package according to the aforementioned burial and sequential build-up method, the burial and lamination are made on the package substrate or main board. Therefore, there is a limit in reducing the size of a device to realize fine pitches. Moreover, when a semiconductor device for high-speed operation is built-in, heat emission is raised as a serious problem. However, since there is a limit in structurally solving the heat emission, there remains a problem in stable operation of the device.

Moreover, since the size and thickness of a package are influenced by a substrate used for lamination, there are limitations in fabricating the package to be thin. Moreover, since an interconnection path from a semiconductor chip to a bump is long, there are difficulties in processing high-speed and high-capacity signals.

Therefore, the present invention is directed to provide an integrated package in a new structure.

Another object of the present invention is to provide a new system-in-package capable of performing a wafer level process.

Another object of the present invention is to provide a system-in-package capable of easily emitting heat and smoothly processing signals upon high speed operation.

The above and other objects and characteristics of the present invention will be more specifically presented in the detailed description of the invention.

In accordance with an aspect of the present invention, the present invention provides a system-in-package including: a substrate of a base wafer which is sawed and on which a semiconductor circuit is formed; a conductive post formed on a top surface of the substrate; at least one semiconductor chip stacked on the top surface of the substrate; a buried layer formed on the top surface of the substrate and at least partially covering the conductive post and the semiconductor chip; and an external connection bump electrically connected to the conductive post.

A redistributed conductive layer electrically connected to an electrode pad of the semiconductor circuit may be formed on the top surface of the substrate, and a thin film electronic device may be further formed on the top surface of the substrate.

The semiconductor chip may be directly electrically connected to the substrate by flip-chip bonding. Further, one surface of the semiconductor chip may be bonded to the top surface of the substrate and electrically connected to the substrate in an indirect manner through the conductive post.

The buried layer may be formed of a resin-based mold, a stacked dielectric layer or a coated dielectric material. The buried layer may be formed to expose one surface of the semiconductor chip.

The conductive post may be directly connected to the external connection bump or it may be indirectly connected to the external connection bump by the redistributed conductive layer.

In accordance with another aspect of the present invention, the present invention provides a method of fabricating a system-in-package, including: forming a conductive post on a top surface of a base wafer at wafer level; stacking a semiconductor chip on the top surface of the base wafer; forming a buried layer for covering the conductive post and the semiconductor chip on the top surface of the base wafer; polishing an upper part of the buried layer so as to expose the conductive post; and forming an external connection bump on the conductive post.

The upper part of the buried layer may be polished, together with the semiconductor chip, to expose one surface of the semiconductor chip and to reduce the thickness of the semiconductor chip. Further, the method may further include: polishing a bottom surface of the base wafer, to significantly reduce the entire thickness of the system-in-package.

### BRIEF DESCRIPTION OF THE DRAWINGS

The above and other features and advantages of the present invention will become more apparent to those of ordinary skill in the art by describing in detail preferred embodiments thereof with reference to the attached drawings in which:

FIG. 1 is a sectional view of a system-in-package according to an embodiment of the present invention;

FIG. 2 is a sectional view of a system-in-package according to another embodiment of the present invention;

FIG. 3 is a sectional view of a system-in-package according to another embodiment of the present invention;

FIG. 4 is a sectional view of a system-in-package according to another embodiment of the present invention; and

FIGS. 5 through 11 are sectional views illustrating a method of fabricating a system-in-package according to the present invention.

### DETAILED DESCRIPTION OF THE INVENTION

The present invention will now be described more fully hereinafter with reference to the accompanying drawings, in which preferred embodiments of the invention are shown.

The terminology used herein is for the purpose of describing particular embodiments only and is not intended to be limiting of example embodiments of the invention. As used herein, the singular forms “a”, “an” and “the” are intended to include the plural forms as well, unless the context clearly indicates otherwise.

The present invention relates to a new buried system-in-package which simplifies the relevant process, improves the product operation characteristics and significantly reduces the product size by forming a buried layer and forming a solder bump while stacking a semiconductor wafer and a semiconductor chip at a wafer level.

FIG. 1 is a sectional view of a system-in-package according to an embodiment of the present invention. As illustrated, a semiconductor chip 200 is stacked on a base substrate 100. The base substrate 100 may use a semiconductor wafer on which a semiconductor circuit, such as a transistor and/or the like, is formed. The base substrate 100 is in the form being sawed, based on a desired package unit.

A bump 210 is formed on the semiconductor chip 200. The semiconductor chip 200 is electrically connected to a top surface of the base substrate 100 through the bump 210, by flip-chip bonding. As illustrated, the semiconductor chip 200 may be stacked on the top surface of the substrate 100 through a redistributed conductive layer 106 electrically connected to an electrode pad 103 on the substrate 100, but the semiconductor chip 200 may be directly connected to the electrode pad (not shown) without using the redistributed conductive layer 106. The semiconductor chip 200 may further comprise a redistributed conductive layer (not shown) electrically connected to the conductive bump 210.

Unlike FIG. 1, the number of the semiconductor chip 200 being stacked on the base substrate 100 may increase.

One or more conductive posts 120 are formed on the top surface of the substrate 100. One surface of the conductive post 120 may be directly connected to an electrode pad 102 formed on the surface of the substrate 100 or it may be connected to the electrode pad 102 through an under bump metal (UBM) 104. The other surface of the conductive post 120 is directly/indirectly connected to an external connection bump 122 as described later.

The conductive post 120 may be formed by a photoresist process. As a material used for the conductive post 120, a high conductive metal and alloy are suitable. In this embodiment, copper (Cu) is used but the material of the conductive post 120 does not need to be limited in particular. Further, unlike FIG. 1, the conductive post 120 may be formed in a post shape in which a vertical height is larger than a horizontal width, to realize fine pitches. Preferably, the height of the conductive post 120 may be the same as or similar to the thickness of the semiconductor chip 200.

Except for the place where the conductive post 120 is formed, a dielectric layer 110 is formed on the surface of the substrate 100.

On the top of the substrate 100, a buried layer 130 is formed to at least partially cover the conductive posts 120 and the semiconductor chip 200. The buried layer 130, while preventing the electrical connection between the conductive posts 120, protects the amounted semiconductor chip 200, and maintains the structural stability of the entire package.

Epoxy resin and/or the like may be used as a material of the buried layer 130. Alternatively, other polymer-based dielectric materials may be used.

The conductive post 120 is electrically connected to the external connection bump 122. The external connection bump 122 and the conductive post 120 may be connected to each other by rewiring layers 107 and 108. The under bump metal (UBM) may be included between the conductive post 120 and the external connection bump 122.

The system-in-package according to the present invention has the advantage of forming the entire thickness of the package to be very thin, by respectively polishing the stacks on the substrate, including the base substrate 100, the buried layer 130, the conductive posts 120 and the semiconductor chip 200, at the wafer level, as described later.

Furthermore, in the system-in-package, the wafer is sawed by a desired unit after a plurality of the semiconductor chips 200 and the other stacks are formed on the base substrate 100 at the wafer level. Therefore, diverse system-in-package suitable for demands of consuming products is mass-produced.

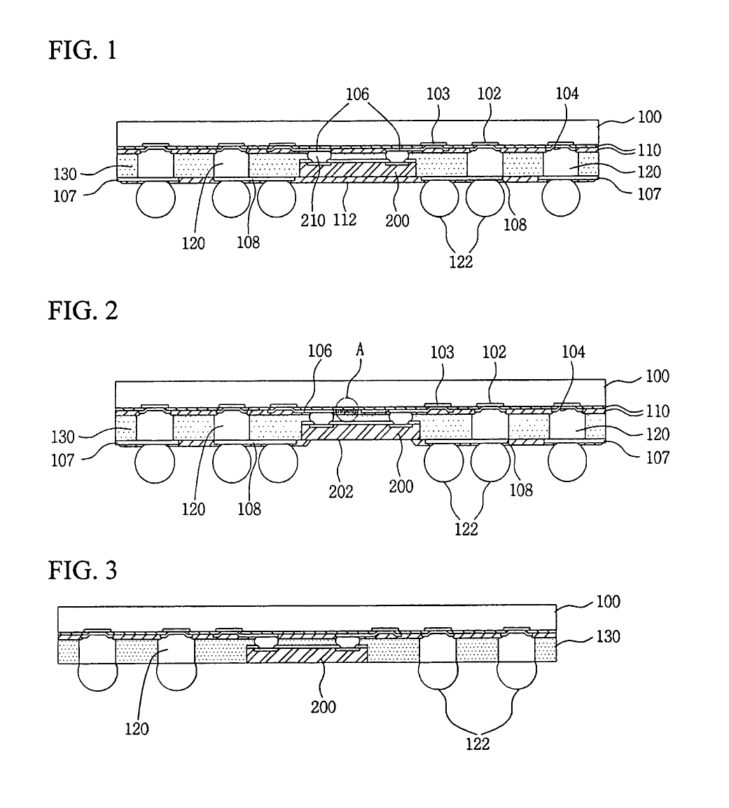

FIG. 2 is a sectional view of a system-in-package according to another embodiment of the present invention.

A buried layer 130 is formed at a lateral surface of a conductive post 120 and a lateral surface of a semiconductor chip 200, exposing a top surface 202 of the semiconductor chip 200 as shown. In this system-in-package, on a base substrate 100 and the semiconductor chip 200 stacked on the base substrate 100, heat emission is easy and a combination with a separate heat spreader or heat sink is easy. Therefore, this system-in-package prevents malfunction caused by generation of heat when the system-in-package operates, thereby improving the reliability of products.

Furthermore, unlike the embodiment of FIG. 1, a thin film electronic device A is formed on the top surface of the base substrate 100. The thin film electronic device A may be, for example, the passive device, such as resistance, capacitor and the like. The thin film electronic device A may be formed during a process of forming a redistributed conductive layer 106 and a dielectric layer 110 or it may be independently formed using a separate mask.

The thin film electronic device A is covered by the buried layer 130 and is blocked from the outside. However, the thin film electronic device A may be electrically connected by the redistributed conductive layer 106 and the like.

FIG. 3 is a sectional view of a system-in-package according to another embodiment of the present invention. A lateral surface of a conductive post 120 is covered by a buried layer 130. The surface of the conductive post 120 is exposed to outward. The conductive post 120 is directly in contact with an external connection bump 122 without using a redistributed conductive layer. A dielectric layer is not formed on the surface of the buried layer 130. An under bump metal (UBM) (not shown) may be further formed between the conductive post 120 and the external connection bump 122, to improve the bonding properties.

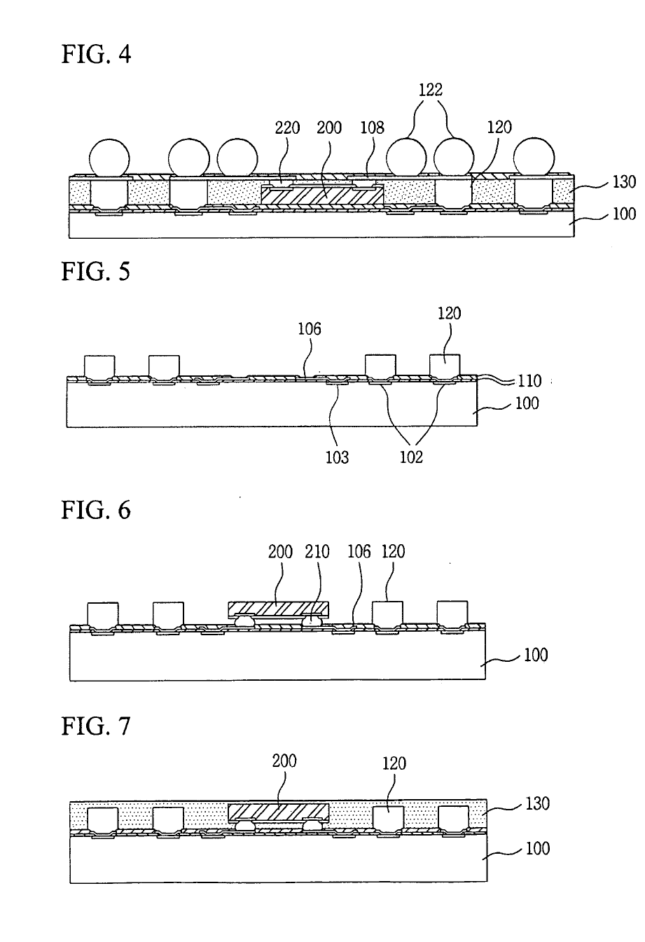

FIG. 4 is a sectional view of a system-in-package according to another embodiment of the present invention. In this embodiment, one surface of a semiconductor chip 200 is directly bonded to a top surface of the base substrate 100. When the semiconductor chip 200 is bonded to the base substrate 100, the semiconductor chip 200 may be stacked on the base substrate 100 by die attachment, using, for example, glue.

A conductive bump or a conductive post 220 is formed on the other surface of the semiconductor chip 200. The conductive post 220 is electrically connected to a conductive post 120 formed on the top surface of the base substrate 100, through a redistributed conductive layer 108.

The above-described embodiments are provided to be helpful in understanding the present invention. Therefore, the number of bumps, the number of semiconductor chips to be stacked, the position of redistributed conductive layers and the like may be variously changed.

Below, a method for fabricating a system-in-package at a wafer level according to a preferred embodiment of the present invention will be described.

FIG. 5 illustrates a base substrate 100 on which a thin film circuit is formed at a wafer level. Although a part of a semiconductor wafer is illustrated for clarity, the base substrate 100 means a single semiconductor wafer on which a plurality of unit integrated circuits are formed.

Electrode pads 102 and 103, which are terminals for external connection of a thin film electrical circuit (not shown), are formed on the base substrate 100. A part of the electrode pad 102 or 103 is connected to a redistributed conductive layer 106. The electrode pad 102 or 103, or the redistributed conductive layer 106 is locally exposed to the outside by a multi-dielectric layer (or protective layer) 110.

A conductive post 120 is formed on a top surface of the base substrate 100 so as to be connected to the electrode pad 102. The conductive post 120 performs a function of a medium to electrically connect the base substrate 100 and a semiconductor chip 200 (to be described later) to the outside. The conductive post 120 may be formed by performing a general photoresist process.

Subsequently, as illustrated in FIG. 6, the semiconductor chip 200 is stacked on the top surface of the base substrate 100. As illustrated, the semiconductor chip 200 may be stacked on the base substrate 100 through a bump 210, by the flip-chip bonding. Alternatively, the semiconductor chip 200 may be stacked on the top surface of the base substrate 100 by the die attachment, like the embodiment of FIG. 4.

Only one semiconductor chip 200 is illustrated for clarity. However, a plurality of semiconductor chips 200 may be two-dimensionally stacked on the top surface of the base substrate 100. The semiconductor chips 200 may include, for example, various semiconductor devices used for diverse application, such as a high-frequency device, a functional integrated circuit device and the like. Further, a wafer level package process is suitable in selecting only the semiconductor chip 200 of a good die through, for example, operation testing.

Subsequently, as illustrated in FIG. 7, a buried layer 130 to cover the conductive post 120 and the semiconductor chip 200 is formed on the top surface of the base substrate 100. The buried layer 130 is formed by using, for example, a resin-based mold, to cover the conductive post 120 and the semiconductor chip 200. However, the buried layer 120 may be formed by stacking a plurality of dielectric layers or coating the top surface of the substrate 100 with a dielectric material.

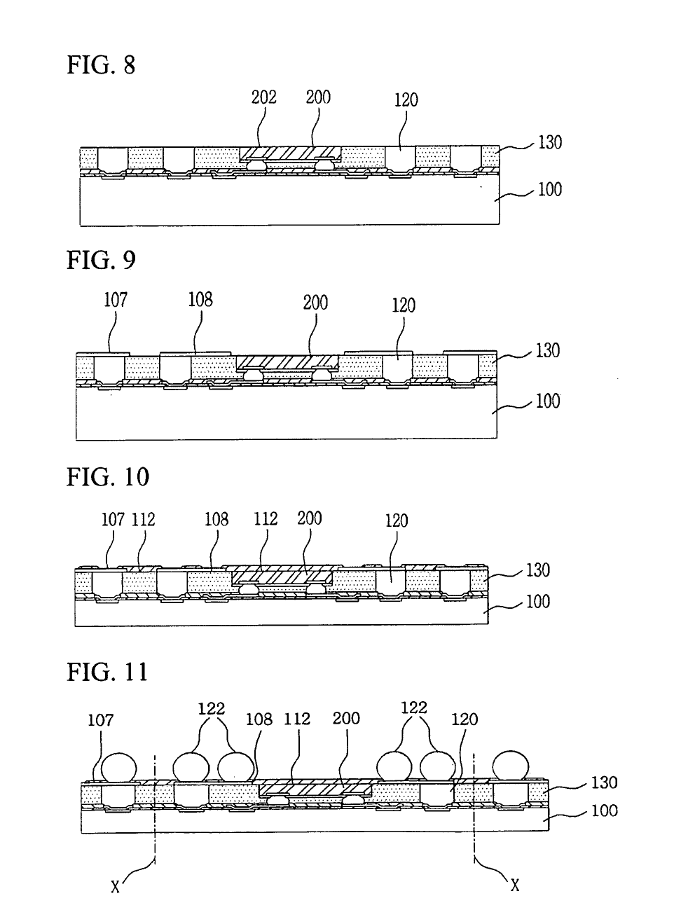

After the buried layer 130 is formed, an upper part of the buried layer 130 is polished to expose the conductive post 120 to the outside (as illustrated in FIG. 8). In the process of polishing the buried layer 130, a top surface 202 of the semiconductor chip 200 may be polished. Therefore, the thickness of the semiconductor chip 200 can be formed to be thinner. In this case, the base substrate 100 acts as a support for the polishing of the buried layer 130 and the semiconductor chip 200.

Subsequently, redistributed conductive layers 107 and 108 may be formed to be electrically connected to the exposed conductive posts 120 (as illustrated in FIG. 9). After the redistributed conductive layers 107 and 108 are formed, a dielectric layer (or a protective layer) 112 is formed on a top surface of the buried layer 130 and on the top surface 202 of the semiconductor chip 200, except for the bump connection region in the redistributed conductive layers 107 and 108 (as illustrated in FIG. 10). For the easy heat emission, the dielectric layer 112 may not be formed on the top surface 202 of the semiconductor chip 200.

When the conductive post 120 and an external connection bump 122 are directly connected to each other, the process of forming the redistributed conductive layers 107 and 108 and the dielectric layer 112 may not be performed.

After the process of FIG. 8 or FIG. 10, the method for fabricating the system-in-package may further comprise the operation of polishing a bottom surface of the base substrate 100. The entire thickness of the system-in-package is changed so as to be very thin at a micrometer level, by polishing the base substrate 100.

Finally, the external connection bump 122 is formed on the exposed redistributed conductive layers 107 and 108, and the base substrate 100 (i.e., wafer) is sawed into unit package regions, along a cutting line X (as illustrated in FIG. 11).

The method for fabricating the system-in-package at the wafer level is capable of fabricating a plurality of packages and is very suitable for forming the thickness of the system-in-package at a very low level.

The system-in-package according to the present invention can be used as a core component of each of various electronic products. When the system-in-package is mounted on the exterior substrate, such as a PCB or the like, or when a plurality of the system-in-package are horizontally or vertically stacked, many various application products can be developed.

In accordance with the present invention, the entire thickness of the package is formed to be very thin through the build-up between the base wafer and one or more semiconductor chips and the polishing of the semiconductor chip, without any additional substrate for stacking, so that the system-in-package meets the miniaturization of consuming electronic devices.

Furthermore, since the electrical path between the semiconductor chip and the base wafer is minimized, the system-in-package has excellent electrical characteristics and is advantageous for high-speed operation.

Furthermore, the system-in-package is realized with the semiconductor chip having no problems of its operation characteristics selected through testing. Therefore, the fabrication process is simplified and the fabrication cost is reduced.

Furthermore, since the surface of the stacked semiconductor chip is exposed to outward, heat emission is easy and a combination with a heat spreader is very easy.

The invention has been described using preferred exemplary embodiments. However, it is to be understood that the scope of the invention is not limited to the disclosed embodiments. On the contrary, the scope of the invention is intended to include various modifications and alternative arrangements within the capabilities of persons skilled in the art using presently known or future technologies and equivalents. The scope of the claims, therefore, should be accorded the broadest interpretation so as to encompass all such modifications and similar arrangements.

What is claimed is:

1. A system-in-package comprising:
a substrate of a sawed base wafer on which a semiconductor circuit is formed;
a conductive post formed on a top surface of the substrate;
at least one semiconductor chip stacked on the top surface of the substrate;
a buried layer formed on the top surface of the substrate so as to cover at least partially the conductive post and the semiconductor chip; and
an external connection bump electrically connected to the conductive post.

2. The system-in-package of claim 1, further comprising:
a redistributed conductive layer formed on the top surface of the substrate so as to be electrically connected to an electrode pad of the semiconductor circuit.

3. The system-in-package of claim 1, further comprising:
a thin film electronic device formed on the top surface of the substrate and covered by the buried layer.

4. The system-in-package of claim 1, wherein the semiconductor chip is electrically connected to the substrate by flip-chip bonding.

5. The system-in-package of claim 1, wherein one surface of the semiconductor chip is bonded to the top surface of the substrate.

6. The system-in-package of claim 1, wherein the buried layer is formed of a resin-based mold, a stacked dielectric layer or a coated dielectric material.

7. The system-in-package of claim 1, wherein the buried layer exposes one surface of the semiconductor chip.

8. The system-in-package of claim 7, wherein the exposed semiconductor chip has an attached heat spreader.

9. The system-in-package of claim 1, wherein the conductive post is electrically connected to the external connection bump by the redistributed conductive layer.

10. The system-in-package of claim 1, wherein the conductive post is directly connected to the external connection bump.

11. A method for fabricating a system-in-package, comprising:
forming a conductive post on a top surface of a base wafer at a wafer level;
stacking at least one semiconductor chip on the top surface of the base wafer;
forming a buried layer on the top surface of the base wafer so as to cover the conductive post and the semiconductor chip;
exposing the conductive post by polishing an upper part of the buried layer; and
forming an external connection bump on the conductive post.

12. The method of claim 11, further comprising:
forming a redistributed conductive layer on the top surface of the base wafer.

13. The method of claim 11, wherein the semiconductor chip is stacked on the top surface of the base wafer by flip-chip bonding or die attachment.

14. The method of claim 11, wherein the buried layer is formed by using a resin-based mold.

15. The method of claim 11, wherein the buried layer is formed by stacking a plurality of dielectric layers.

16. The method of claim 11, wherein the buried layer is formed by coating the top surface of the base wafer with a dielectric material.

17. The method of claim 11, wherein one surface of the semiconductor chip is exposed by polishing an upper part of the buried layer.

18. The method of claim 11, further comprising:
forming a redistributed conductive layer to be electrically connected to the exposed conductive post.

19. The method of claim 11, further comprising:
polishing a bottom surface of the base wafer.
